(19) United States
(12) Patent Application Publication
(10) Pub. No.: US 2011/0287613 A1
(43) Pub. Date: Nov. 24, 2011

(54) MANUFACTURING METHOD OF SUPERJUNCTION STRUCTURE

(76) Inventors: Jiquan Liu, Shanghai (CN); Shengan Xiao, Shanghai (CN)

(21) Appl. No.: 13/106,778

(22) Filed: May 12, 2011

(30) Foreign Application Priority Data
May 20, 2010 (CN) 201010180113.6

(51) Int. Cl. H01L 21/20

(52) U.S. Cl. 438/478; 257/E21.09

(57) ABSTRACT

A manufacturing method of superjunction structure is disclosed. After the growth of an epitaxial layer on a substrate, deep trenches are etched in the epitaxial layer. A mixture of silicon source gas, hydrogen gas, halide gas and doping gas is used for trench tilling by means of epitaxial growth. The epitaxial growth rate on trench sidewalls near the bottom of the trench is set to be higher than that near the top of the trench by adjusting the flow rates of the silicon source gas and the halide gas and other parameters. By changing the flow rate of the doping gas at different stages of the epitaxial filling process, the trenches can be filled with epitaxial layers of different doping concentrations, with higher doping concentration near the bottom and lower doping concentration near the top.

### CROSS-REFERENCES TO RELATED APPLICATIONS

This application claims the priority of Chinese patent application number 201010180113.6, filed on May 20, 2010, the entire contents of which are incorporated herein by reference.

### FIELD OF THE INVENTION

The present invention relates to an IC manufacturing method, and more particularly to a manufacturing method of a superjunction structure.

### BACKGROUND

It is known that a superjunction structure as shown in FIG. 1 is often used as a power MOSFET having both high withstand voltage and low on resistance. In FIG. 1, an N type region 2 is formed on a semiconductor substrate 1. P type regions 3 are tilled in the N type region 2 to form alternating P type and N type regions. A body contact region 5, a source region 6, and a P+ implantation region 7 are arranged at both sides of each P type region 3 from outside in. Gate insulating films and gate electrodes 4 are formed on the N type region 2. Insulating films 8 are deposited on the gate electrodes 4. A source metal electrode 9 is formed to cover the insulating films 8 and the P type regions 3. A drain electrode 10 is formed on the backside of the semiconductor substrate 1.

It is not easy to manufacture the aforementioned superjunction structure, especially the alternately arranged P type 3 an N type 2 pillars. In the prior art, there are mainly two methods of manufacturing superjunction structures.

The first manufacturing method of superjunction structure is shown in FIG. 2. Firstly, grow a 1st N type epitaxial layer 22a on a substrate 21, afterwards, implant P type dopants into the 1st N type epitaxial layer to form a 1st implantation region 23a. Secondly, grow a 2nd N type epitaxial layer 22b on the 1st N type epitaxial layer, and then, implant P type dopants into the 2nd N type epitaxial layer 22b to form a 2nd implantation region 23b. Repeat the steps of epitaxial growth and implantation until the thickness of the N type epitaxial layer meets the requirement, wherein, the implantation regions are vertically aligned with one another. Finally, diffuse the P type dopants to form a P type pillar 25 by anneal. In this way, a complete P (or N) type pillar is finished.

The problems of the first method include: high cost, since epitaxial growth and implantation are both processes of high cost in semiconductor manufacturing; difficulty in process control, as the several times of epitaxial growth require the same resistivity and film quality; requirement of high alignment accuracy, since the dopants are required to be implanted at the same position.

Another manufacturing method of superjunction structure is shown in FIG. 3. Firstly, grow a thick N type epitaxial layer 32 on the substrate 31. Secondly, etch the N type epitaxial layer 32 to form trenches 35. Thirdly, fill P type epitaxial material 33 in the trenches 35 by P type epitaxial filling process. Finally, planarize the top of the trenches 35 by CMP process. The cost of this manufacturing method is lower than the first method, but the process is much more difficult as the steps of etching and filling the deep trenches 35 (the depth is typically 40 um) are difficult to control. In order to decrease the difficulty of the process, usually a part of the N type epitaxial layer 32 is left between the bottom of the deep trenches 35 and the substrate 31, and the doping concentration of the P type epitaxial layer 33 in the deep trenches 35 is uniform, as a result, the part of the N type epitaxial layer 32 between the bottom of the deep trenches 35 and the substrate 31 cannot be fully depleted in an off-state, thus reducing the breakdown voltage of the device.

### BRIEF SUMMARY OF THE DISCLOSURE

An objective of the present invention is to fully deplete the epitaxial layer between the bottom of the deep trenches and the substrate so as to raise the breakdown voltage of a superjunction device.

To achieve the aforementioned objective, the present invention provides a manufacturing method of superjunction structure having alternating P type and N type regions, which comprises the following steps:

step 1: grow an N type epitaxial layer on a substrate;

step 2: form trenches in the N type epitaxial layer by etch;

step 3: fill the trenches with P type epitaxial layers by means of P type epitaxial growth in the trenches by using a mixture of silicon source gas, hydrogen gas, halide gas, and doping gas.

In the above manufacturing method, the N type epitaxial layer in steps 1 and 2 can be replaced by a P type epitaxial layer; correspondingly, the P type epitaxial layer and P type epitaxial growth in step 3 should be replaced by an N type epitaxial layer and N type epitaxial growth.

During the process of P type or N type epitaxial growth in step 3, the epitaxial growth rate on trench sidewalls at a lower part of the trench is higher than that at an upper part of the trench, and the doping concentration of P type or N type epitaxial layer near the bottom of the trench is higher than the doping concentration at elsewhere in the trench.

The manufacturing method may further comprise step 4: planarize the top of the trenches by CMP.

Preferably, the thickness of the P type or N type epitaxial layer in step 1 is in a range of 1.0˜100.0 μm; the width and depth of the trenches are respectively in a range of 0.2˜10.0 μm and 0.8˜98.0 μm.

The P type or N type epitaxial growth in step 3 is performed under a temperature of 800˜1000 and a pressure of 0.01˜760 torr.

The silicon source gas is at least one of SiH3Cl, SiH2Cl2, SiHCl3 and SiCl4.

The halide gas is at least one of HCI and HF.

The doping gas can be boron hydride during P type epitaxial growth; the doping gas can be at least one of phosphine and arsenic hydride during N type epitaxial growth.

Compared with existing uniformly doped epitaxial layer in the trenches, the present invention adopts nonuniform epitaxial growth during the trench filling process to achieve high doping concentration near the bottom of the trenches and lower doping concentration at other parts of the trenches, thereby enabling the depletion of the part of epitaxial layer between the bottom of the trenches and the surface of the substrate, thus increasing the breakdown voltage of the device.

### BRIEF DESCRIPTION OF THE DRAWINGS

FIG. 1 is a sectional view of a superjunction device;

FIG. 2 is a schematic view of a manufacturing method of superjunction structure in the prior art;

FIG. 3 is a schematic view of another manufacturing method of superjunction structure in the prior art;

FIGS. 4˜8 are sectional views of the manufacturing method according to one embodiment of the present invention;

FIG. 9 is a flow chart of the manufacturing method according to one embodiment of the present invention.

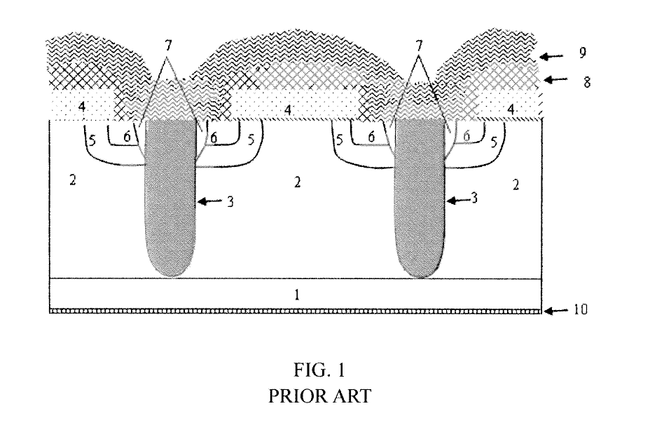

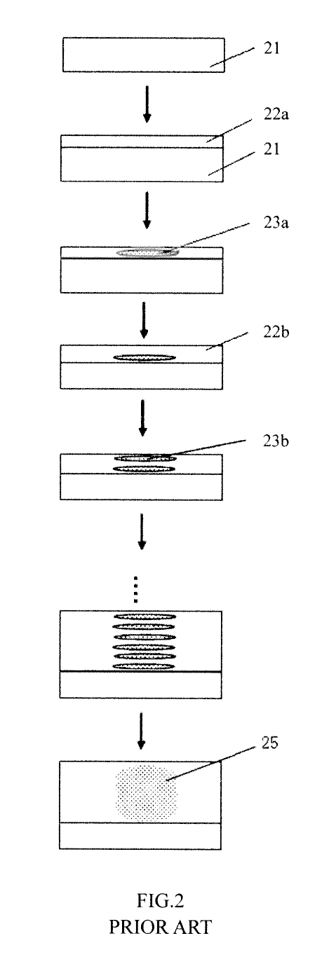

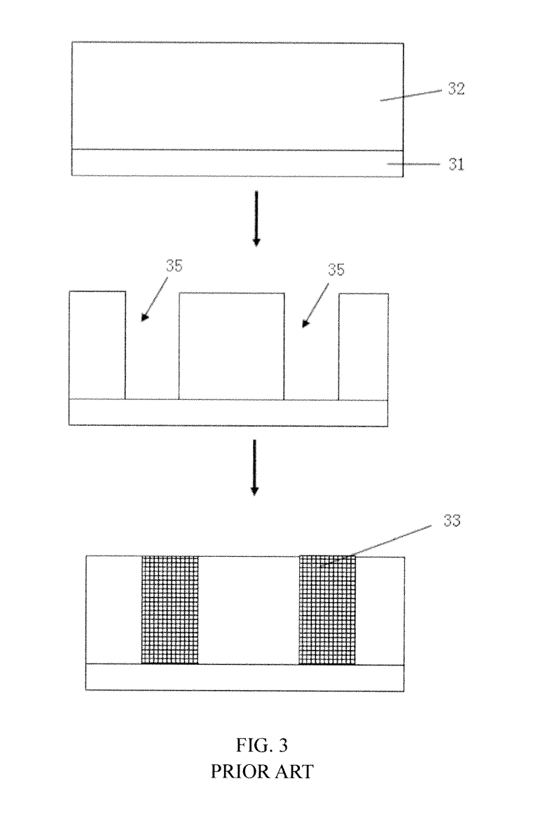

### DETAILED DESCRIPTION

In the following detailed description of the present invention, a superjunction NMOSFET will be taken as an example to give some detailed explanations. Those skilled in the art shall understand that the same manufacturing method can also be applied to a PMOSFET by changing all the N-types to P-types and P-types to N-types.

The manufacturing method of superjunction structure according to the present invention adopts silicon source gas, hydrogen gas, halide gas and doping gas as reaction gases during the step of trench filling by means of P type epitaxial growth. Since the halide gas has a character of silicon etching, the epitaxial growth rate on trench sidewalls at the lower part of the trench can be higher than the epitaxial growth rate on trench sidewalls at the upper part of the trench. In the present invention, the epitaxial growth rates on trench sidewalls at the lower and upper parts of the trench are controlled by adjusting the flow rates of the silicon source gas and the halide gas, and also by adjusting other parameters such as temperature, pressure, flow rate of hydrogen gas, etc.

Since the epitaxial growth rate at the lower part is higher, the P type epitaxial layer is firstly formed near the bottom of the trench. By changing the flow rate of the doping gas (e.g. boron hydride) or by changing other parameters (e.g. temperature, pressure, flow rate of hydrogen gas) at different time periods during the epitaxial growth process, the doping concentration of epitaxial layer near the bottom of the trench can be controlled to be higher than the doping concentration of epitaxial layer away from the bottom of the trench. Preferably, this can be achieved by supplying doping gas with high flow rate at the beginning of the epitaxial growth process (initial stage) to grow epitaxial layer with high doping concentration near the bottom of the trench; after a period, reduce the flow rate of the doping gas to grow epitaxial layer with relatively low doping concentration away from the bottom of the trench during a later stage of epitaxial growth. As the epitaxial layer grown during the initial stage is near the bottom of the trench and the epitaxial layer grown during the later stage is away from the bottom of the trench, the epitaxial layer tilled in the trench can be divided into two parts in terms of doping concentration, namely a lower part of epitaxial layer (see layer A in FIG. 8) near the bottom of the trench and an upper part of epitaxial layer (see layer B in FIG. 8) away from the bottom of the trench. The epitaxial growth process can also be performed by using two steps: firstly at the beginning of epitaxial growth, form the lower part of epitaxial layer in the trench by controlling the epitaxial growth rate on trench sidewalls at the lower part of the trench to be considerably higher than that near the top of the trench; secondly after a period, let the growth rate on trench sidewalls near the top of the trench be approximately the same as the growth rate on trench sidewalls at the lower part of the trench and form the upper part of epitaxial layer near the top of the trench; wherein the doping concentration of the lower part of epitaxial layer is higher than the doping concentration of the upper part of epitaxial layer.

Let the width (CD) of the trench be m, the spacing between adjacent trenches be w, the distance from the bottom of the trench to the surface of the substrate be t2; the average thickness of the lower part of epitaxial layer be t1, the doping concentration of the lower part of epitaxial layer be x1, the doping concentration of the upper part of epitaxial layer be x2 (refer to FIGS. 6˜8). According to the superjunction principle, the above parameters shall satisfy the formula of x1/x2=1+mt2/wt1. Preferably, t1/t2=m/w and x1=2x2.

Hereinafter, preferred embodiments of the present invention be described in detail with reference to accompanying drawings.

### Embodiment 1

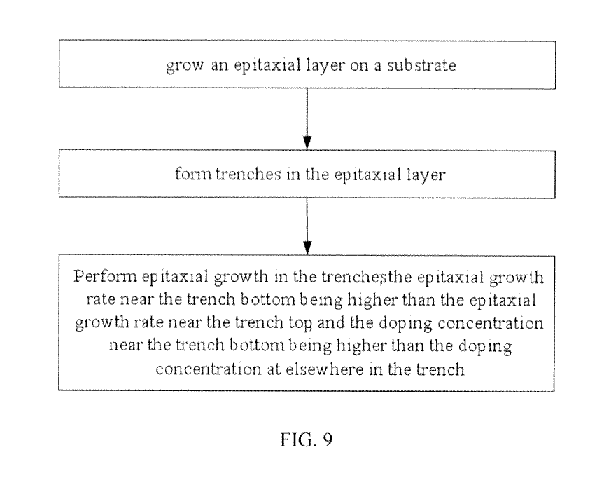

Refer to FIG. 9, the manufacturing method of superjunction structure according to the first embodiment comprises the following steps:

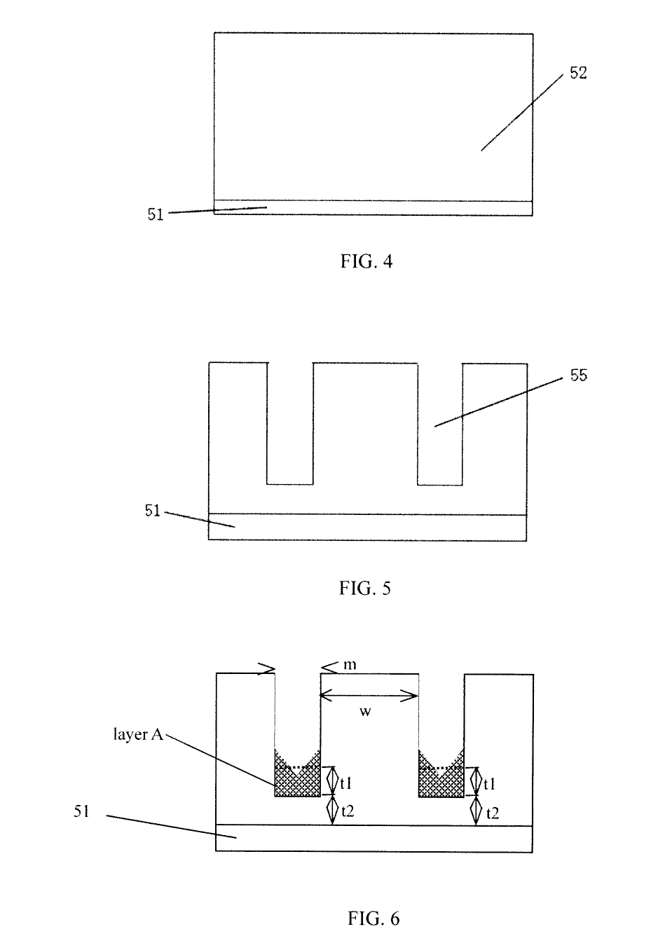

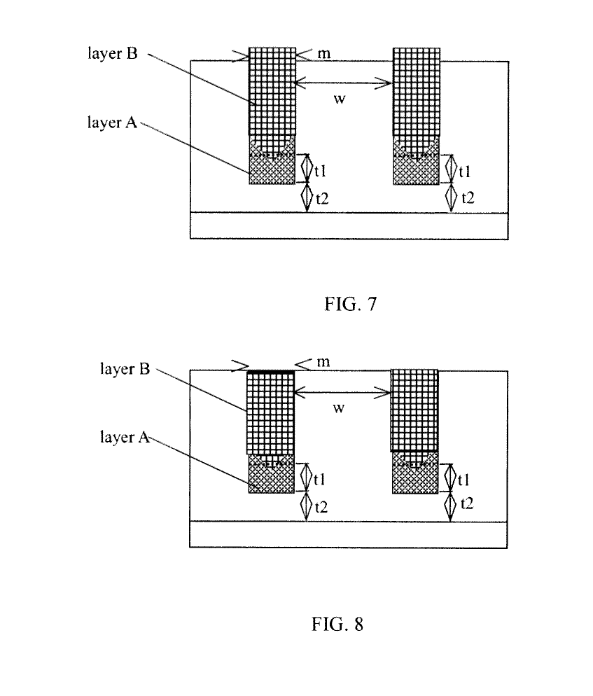

As shown in FIG. 4, firstly grow an N type epitaxial layer 52 on an N type substrate 51, wherein the substrate 51 is a highly doped N type substrate. The thickness of the N type epitaxial layer 52 is in a range of 40.0 μm to 50.0 μm.

Next, as shown in FIG. 5, grow one or more silicon oxide layers on the epitaxial layer 52 and etch the epitaxial layer 52 to form trenches 55 in the epitaxial layer 52 by using the silicon oxide layers as hard mask. The depth of the trenches 55 is in a range of 35.0 μm to 50.0 μm. The silicon oxide layers can be removed or remained after trench etching. If silicon oxide hard mask is remained, selective epitaxial growth can be subsequently performed by adjusting the ratio between the flow rate of silicon source gas and the flow rate of halide gas to prevent the growth of silicon on the silicon oxide layers.

Afterwards, fill the trenches by means of P type epitaxial growth in the trenches 55. A mixture of silicon source gas, hydrogen gas, halide gas and doping gas is used as reaction gas during the process of P type epitaxial growth. For different silicon source gases, different growth temperatures and pressures are used. Preferably, silicon source gas with higher content of chlorine should adopt higher reaction temperature and higher pressure, or defects are likely to form. By adjusting the ratio between the flow rates of the silicon source gas and the halide gas as well as other parameters (such as temperature, pressure, flow rate of hydrogen gas, etc.), the epitaxial growth rate on trench sidewalls at the lower part of the trench is high while the epitaxial growth rate on trench sidewalls at the upper part of the trench is low. In the initial stage of P type epitaxial growth, a doping gas with high flow rate is supplied to initially form epitaxial layer with high doping concentration near the bottom of the trench (see layer A in FIG. 6). Then, decrease the flow rate of the doping gas to form epitaxial layer with low doping concentration in the later stage (see layer B in FIG. 7). In this way, a trench is completely filled by two epitaxial layers, namely layer A (having an average thickness of t1) and layer B. After trench filling, the surface of the P type epitaxial layer will be higher than the surface of the N type epitaxial layer 52 due to over growth of the epitaxial material. Therefore, as shown in FIG. 8, finally planarize the surface of the trenches by chemical mechanical polishing.

In this embodiment, the hard mask used for trench etching (namely the one or more silicon oxide layers) can be formed by high temperature oxidation (HTO) or chemical vapor deposition (CVD) or both HTO and CVD. The hard mask can also be made of nitride or nitrogen oxide or a combination of two or three of oxide, nitride and nitrogen oxide. After etching the trenches 55, the hard mask can be completely remained or partly remained or completely removed before P type epitaxial growth. If the hard mask is remained before the step of P type epitaxial growth, the hard mask can be removed after epitaxial growth, or be remained and used as a stop layer during the CMP process and be removed after the CMP process.

### Embodiment 2

This embodiment is different from Embodiment 1 in that: during the step of trench filling by means of P type epitaxial growth, the epitaxial growth rate on trench sidewalls at the lower part of the trench is set to be considerably higher than that near the top of the trench by adjusting the ratio between the flow rates of the silicon source gas and the halide gas as well as other parameters in the initial stage. Meanwhile, a doping gas with high flow rate is supplied, so that the epitaxial layer formed near the bottom of the trench has a high doping concentration (see layer A in FIG. 6). Afterwards, adjust the flow rates of the silicon source gas and the halide gas to raise the epitaxial growth rate on trench sidewalls near the top of the trench, and at the same time decrease the flow rate of the doping gas, so that the epitaxial layer formed in the later stage away from the bottom of the trench has a low doping concentration (see layer B in FIG. 7).

### Embodiment 3

This embodiment is different from Embodiment 1 in that: after forming the N type epitaxial layer 52, one or more silicon oxide layers are grown on the N type epitaxial layer 52, wherein the one or more silicon oxide layers can prevent silicon epitaxial growth at the top of the trench during the subsequent trench filling process, in this way, the opening of the trench will not be easily closed, thus reducing the difficulty of the trench filling process; afterwards, form a patterned photoresist layer on the silicon oxide layers and etch the silicon oxide layers and the N type epitaxial layer 52 by using the patterned photoresist layer as hard mask to form the trenches 55; finally, remove the photoresist layer after trench etching.

The silicon oxide layers can be removed after trench filling, or be remained and used as a stop layer during the CMP process and be removed after the CMP process.

### Embodiment 4

This embodiment is different from Embodiment 2 in that: after forming the N type epitaxial layer 52, one or more silicon oxide layers are grown on the N type epitaxial layer 52, wherein the one or more silicon oxide layers can prevent silicon epitaxial growth at the top of the trench during the subsequent trench filling process, in this way, the opening of the trench will not be easily closed, thus reducing the difficulty of the trench filling process; afterwards, form a patterned photoresist layer on the silicon oxide layers and etch the silicon oxide layers and the N type epitaxial layer 52 by using the patterned photoresist layer as hard mask to form the trenches 55; finally, remove the photoresist layer after trench etching.

The silicon oxide layers can be removed after trench filling, or be remained and used as a stop layer during the CMP process and be removed after the CMP process.

### Embodiment 5

This embodiment is different from Embodiment 1 in that: after growing the N type epitaxial layer 52, form a patterned photoresist layer on the N type epitaxial layer 52 and etch the N type epitaxial layer 52 to form trenches 55 by using the patterned photoresist layer as hard mask; afterwards, remove the photoresist layer. In other words, in embodiment 5, no silicon oxide layer is formed on the N type epitaxial layer 52.

### Embodiment 6

This embodiment is different from Embodiment 2 in that: after growing the N type epitaxial layer 52, form a patterned photoresist layer on the N type epitaxial layer 52 and etch the N type epitaxial layer 52 to form trenches 55 by using the patterned photoresist layer as hard mask; afterwards, remove the photoresist layer. In other words, in embodiment 5, no silicon oxide layer is formed on the N type epitaxial layer 52.

In the above embodiments, the epitaxial layer 52 can also be a P type epitaxial layer, and correspondingly the trenches 55 are filled with N type epitaxial layers, wherein, the silicon source gas is at least one of SiH3Cl, SiH2Cl2, SiHCl3 and SiCl4; the halide gas is at least one of HCl and HF; the doping gas is at least one of phosphine (e.g. PH3) and arsenic hydride (e.g. AsH3). The temperature of the N type epitaxial growth is 800˜1000° C. The pressure of the N type epitaxial growth is 0.01˜760 torr.

In the above embodiments, the depth of the trenches 55 and the thickness of the epitaxial layer 52 are used for illustrative purposes only. They do not constitute restriction to the scope of the present invention within the aforesaid embodiments. A depth of the deep trenches other than 35.0˜50.0 μm but within the range of 0.8˜98.0 μm, and a thickness of the epitaxial layer other than 40.0˜50.0 μm but within the range of 1.0˜100.0 μm are also applicable to the present invention. Furthermore, the width (or critical dimension) of the trenches can be designed within a range of 0.2˜10.0 μm according to the depth of the trenches.

In the above embodiments, the different doping concentrations within the trench can be obtained by using other methods, such as by controlling the temperature, the pressure, the flow rate of silicon source gas, etc. All these methods to achieve non-uniformly doped epitaxial layers in the trenches (with high doping concentration near the bottom and low doping concentration at elsewhere) are within the scope of the present invention.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A manufacturing method of superjunction structure, comprising:
step 1: growing an N type epitaxial layer on a substrate;
step 2: forming trenches in the N type epitaxial layer;
step 3: filling the trenches with P type epitaxial layers by means of P type epitaxial growth in the trenches by using a mixture of silicon source gas, hydrogen gas, halide gas and doping gas; wherein,
during the process of P type epitaxial growth, an epitaxial growth rate on trench sidewalls at a lower part of the trench is higher than an epitaxial growth rate on trench sidewalls at an upper part of the trench, and the doping concentration of P type epitaxial layer near a bottom of the trench is higher than the doping concentration of P type epitaxial layer at elsewhere in the trench.

2. The method according to claim 1, further comprising:
step 4, planarizing top of the trenches by chemical mechanical polishing.

3. The method according to claim 1, wherein the N type epitaxial layer as formed in step 1 has a thickness of 1.0 μm to 100.0 μm.

4. The method according to claim 1, wherein the trenches as formed in step 2 each has a width of 0.2 μm to 10.0 μm, and a depth of 0.8 μm to 98.0 μm, the depth being smaller than the thickness of the N type epitaxial layer.

5. The method according to claim 1, wherein the P type epitaxial growth in step 3 is performed under a temperature of 800 to 1000, and a pressure of 0.01 torr to 760 torr.

6. The method according to claim 1, wherein the silicon source gas is at least one of SiH3Cl, SiH2Cl2, SiHCl3 and SiCl4.

7. The method according to claim 1, wherein the halide gas is HCl or HF.

8. The method according to claim 1, wherein the doping gas is boron hydride.

9. The method according to claim 1, wherein the process of P type epitaxial growth further comprises:
adjusting flow rates of the silicon source gas and the halide gas to achieve a high epitaxial growth rate on trench sidewalls at a lower part of the trench and a low epitaxial growth rate on trench sidewalls at an upper part of the trench; supplying a doping gas with high flow rate to form a lower part of P type epitaxial layer with high doping concentration;
decreasing the flow rate of the doping gas to form an upper part of P type epitaxial layer with low doping concentration in the trench.

10. The method according to claim 1, wherein the process of P type epitaxial growth further comprises:
adjusting flow rates of the silicon source gas and the halide gas to achieve an epitaxial growth rate on trench sidewalls at a lower part of the trench considerably higher than an epitaxial growth rate on trench sidewalls at an upper part of the trench; supplying a doping gas with high flow rate to form a lower part of P type epitaxial layer with high doping concentration;
adjusting the flow rates of the silicon source gas and the halide gas to raise the epitaxial growth rate on trench sidewalls at the upper part of the trench; decreasing the flow rate of the doping gas to form an upper part of P type epitaxial layer with low doping concentration in the trench.

11. A manufacturing method of superjunction structure, comprising:
step 1: growing a P type epitaxial layer on a substrate;
step 2: forming trenches in the P type epitaxial layer;
step 3: filling the trenches with N type epitaxial layers by means of N type epitaxial growth in the trenches by using a mixture of silicon source gas, hydrogen gas, halide gas and doping gas; wherein,
during the process of N type epitaxial growth, an epitaxial growth rate on trench sidewalls at a lower part of the trench is higher than an epitaxial growth rate on trench sidewalls at an upper part of the trench, and the doping concentration of N type epitaxial layer near a bottom of the trench is higher than the doping concentration of N type epitaxial layer at elsewhere in the trench.

12. The method according to claim 11, further comprising:
step 4, planarizing top of the trenches by chemical mechanical polishing.

13. The method according to claim 11, wherein the P type epitaxial layer as formed in step 1 has a thickness of 1.0 μm to 100.0 μm.

14. The method according to claim 11, wherein the trenches as formed in step 2 each has a width of 0.2 μm to 10.0 μm, and a depth of 0.8 μm to 98.0 μm, the depth being smaller than the thickness of the P type epitaxial layer.

15. The method according to claim 11, wherein the N type epitaxial growth in step 3 is performed under a temperature of 800 to 1000, and a pressure of 0.01 torr to 760 torr.

16. The method according to claim 11, wherein the silicon source gas is at least one of SiH3Cl, SiH2Cl2, SiHCl3 and SiCl4.

17. The method according to claim 11, wherein the halide gas is HCl or HF.

18. The method according to claim 1, wherein the doping gas is at least one of phosphine and arsenic hydride.

19. The method according to claim 11, wherein the process of N type epitaxial growth further comprises:
adjusting flow rates of the silicon source gas and the halide gas to achieve a high epitaxial growth rate on trench sidewalls at a lower part of the trench and a low epitaxial growth rate on trench sidewalls at an upper part of the trench; supplying a doping gas with high flow rate to form a lower part of N type epitaxial layer with high doping concentration;
decreasing the flow rate of the doping gas to form an upper part of N type epitaxial layer with low doping concentration in the trench.

20. The method according to claim 11, wherein the process of N type epitaxial growth further comprises:
adjusting flow rates of the silicon source gas and the halide gas to achieve an epitaxial growth rate on trench sidewalls at a lower part of the trench considerably higher than an epitaxial growth rate on trench sidewalls at an upper part of the trench; supplying a doping gas with high flow rate to form a lower part of N type epitaxial layer with high doping concentration;
adjusting the flow rates of the silicon source gas and the halide gas to raise the epitaxial growth rate on trench sidewalls at the upper part of the trench; decreasing the flow rate of the doping gas to form an upper part of N type epitaxial layer with low doping concentration in the trench.
